(19) United States
(12) Patent Application Publication
(10) Pub. No.: US 2015/0064839 A1
(43) Pub. Date: Mar. 5, 2015

(54) METHOD OF FORMING TIN OXIDE SEMICONDUCTOR THIN FILM

(71) Applicants: SAMSUNG DISPLAY CO., LTD., Yongin-City (KR); Industry-Academic Cooperation Foundation, Yonsei University, Seoul (KR)

(72) Inventors: Chaun-Gi CHOI, Yongin-City (KR); Yeon-Gon MO, Yongin-City (KR); Hyun-Jae KIM, Seoul (KR); Hyun-Soo LIM, Seoul (KR); Si-Joon KIM, Seoul (KR); Tae-Soo JUNG, Seoul (KR); You-Seung RIM, Seoul (KR)

(21) Appl. No.: 14/333,744

(22) Filed: Jul. 17, 2014

(30) Foreign Application Priority Data
Aug. 29, 2013 (KR) 10-2013-0103425

(51) Int. Cl. H01L 29/24; H01L 21/02

(52) U.S. Cl. CPC H01L 29/24; H01L 21/02565; H01L 21/02664
USPC 438/104

(57) ABSTRACT

A method of forming a tin oxide semiconductor thin film includes preparing a precursor solution including a tin oxide semiconductor, coating the precursor solution on a substrate; and performing a heat treatment on the substrate coated with the precursor solution. A tin compound having a different tin valence according to a semiconductor type of the tin oxide semiconductor may be used in the precursor solution.

### CROSS-REFERENCE TO RELATED APPLICATION

Korean Patent Application No. 10-2013-0103425, filed on Aug. 29, 2013, in the Korean Intellectual Property Office, and entitled: “Method Of Forming Tin Oxide Semiconductor Thin Film,” is incorporated by reference herein in its entirety.

### BACKGROUND

1. Field

Example embodiments relate to a method of forming a tin oxide semiconductor thin film.

2. Description of the Related Art

Oxide semiconductors may be used to manufacture a semiconductor layer, for example, for use in an electronic device.

### SUMMARY

Embodiments are directed to a method of forming a tin oxide semiconductor thin film, the method including preparing a precursor solution including a tin compound, applying the precursor solution on a substrate, and subjecting the substrate with the precursor solution applied thereon to a heat treatment to form the tin oxide semiconductor thin film. The tin compound used in the precursor solution may have a different tin valence according to a semiconductor type of the tin oxide semiconductor thin film.

The preparing of the precursor solution may include dissolving the tin compound in a solvent.

The tin compound may be selected from a divalent tin salt and a quadrivalent tin salt.

The tin compound may be a divalent tin salt, and the divalent tin salt may include at least one of tin(II) chloride, tin(II) iodide, tin(II) chloride dihydrate, tin(II) bromide, tin(II) fluoride, tin(II) oxalate, tin(II) sulfide, or tin(II) acetate.

The tin compound may be a quadrivalent tin salt, and the quadrivalent tin salt may include at least one of tin(IV) chloride, tin(IV) chloride pentahydrate, tin(IV) fluoride, tin(IV) iodide, tin(IV) sulfide or tin(IV) tert-butoxide.

The tin compound may be a divalent tin salt, and the divalent tin salt may be used to form a p-type tin oxide semiconductor.

The p-type tin oxide semiconductor may include SnO.

The tin compound may be a quadrivalent tin salt, and the quadrivalent tin salt may be used to form an n-type tin oxide semiconductor.

The n-type tin oxide semiconductor may include SnO₂.

A concentration of the tin compound relative to the total precursor solution may be from about 0.1 M to about 10 M.

The preparing of the precursor solution of the tin oxide semiconductor may be performed at a temperature of about 50° C. to about 80° C.

The heat treatment may include a first heat treatment performed at a temperature of about 100° C. to about 300° C.

The heat treatment may further include a second heat treatment performed at a temperature of about 300° C. to about 500° C.

The first heat treatment may be performed for about 1 minute to about 10 minutes, and the second heat treatment may be performed for about 1 hour to about 3 hours.

At least one of the first heat treatment and the second heat treatment may be performed in an oxygen atmosphere.

The precursor solution may be applied on the substrate by spin coating, dip coating, inkjet printing, screen printing, a spray process, or a roll-to-roll process.

The tin oxide semiconductor thin film may be amorphous.

The heat treatment may be performed by using a hot-plate, a furnace, or via rapid heat treatment.

The heat treatment may be performed in an oxygen atmosphere.

Embodiments are also directed to a method of forming a tin oxide semiconductor thin film, the method including preparing a precursor solution including a tin compound, the tin compound having a first valence or a second valence, wherein the first valence is different from the second valence, applying the precursor solution on a substrate, and subjecting the substrate and precursor solution applied thereon to a heat treatment to form the tin oxide semiconductor thin film. A semiconductor type of the tin oxide semiconductor thin film may be controlled by selecting the tin compound having the first valence or the tin compound having the second valence.

### BRIEF DESCRIPTION OF THE DRAWINGS

Features will become apparent to those of skill in the art by describing in detail exemplary embodiments with reference to the attached drawings in which:

FIG. 1 illustrates a flowchart showing a method of forming a tin oxide semiconductor thin film, according to an exemplary embodiment;

FIG. 2 illustrates a graph of a drain current (Id) vs. a gate voltage (Vg) of thin film transistors according to Examples 1 to 4; and

FIG. 3 illustrates a graph showing a hole concentration according to Experimental Examples 1 and 2.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. As used herein, the term “and/or” includes any and all combinations of one or more of the associated listed items.

In the drawing figures, the dimensions of layers and regions may be exaggerated for clarity of illustration. Like reference numerals refer to like elements throughout.

As used herein, the expression “a tin oxide semiconductor” refers to an oxide semiconductor including SnOₓ (1≦x≦2), which may be a p-type semiconductor or an n-type semiconductor.

A method of forming a tin oxide semiconductor thin film according to an exemplary embodiment will be described in detail herein below.

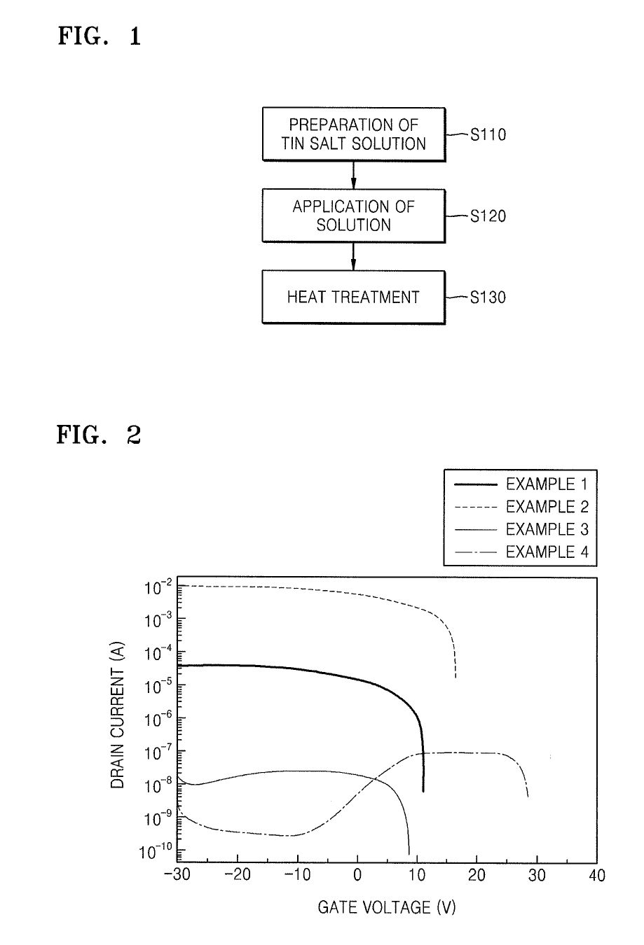

FIG. 1 illustrates a flowchart illustrating a method of forming a tin oxide semiconductor thin film, according to an exemplary embodiment. Referring to FIG. 1, a method of forming a tin oxide semiconductor thin film may include preparing a precursor solution including a tin compound for a tin oxide semiconductor (S110), applying the precursor solution on a substrate (S120); and subjecting the substrate applied with the precursor solution to a heat treatment (e.g., baking).

The precursor solution of the tin oxide semiconductor may be formed by dissolving a tin compound in a solvent (S110). The tin compound may include, for example, a divalent tin salt or a quadrivalent tin salt. For example, the divalent tin salt may include at least one of tin(II) chloride, tin(II) iodide, tin(II) chloride dihydrate, tin(II) bromide, tin(II) fluoride, tin(II) oxalate, tin(II) sulfide, or tin(II) acetate.

For example, the quadrivalent tin salt may include at least one of tin(IV) chloride, tin(IV) chloride pentahydrate, tin(IV) fluoride, tin(IV) iodide, tin(IV) sulfide, or tin(IV) tert-butoxide.

In certain example embodiments, the tin compound having the first valence may be a divalent tin salt, and the tin compound having the second valence may be a quadrivalent tin salt.

The solvent may include, e.g., one or more of deionized water, methanol, ethanol, propanol, isopropanol, 2-methoxyethanol, 2-ethoxyethanol, 2-propoxyethanol 2-butoxyethanol, methyl cellosolve, ethyl cellosolve, diethyleneglycolmethylether, ethyleneglycolethylether, dipropyleneglycolmethylether, toluene, xylene, hexane, heptane, octane, ethyl acetate, butyl acetate, diethyleneglycoldimethylether, diethyleneglycoldimethylethylether, methylmethoxypropionic acid, ethylethoxypropionic acid, ethyl lactate, propyleneglycolmethyletheracetate, propyleneglycolmethylether, propyleneglycolpropylether, methyl cellosolve acetate, ethyl cellosolve acetate, diethyleneglycolmethylacetate, diethyleneglycolethylacetate, acetone, methyl isobutylketone, cyclohexanone, dimethylformamide (DMF), N,N-dimethylacetamide (DMAc), N-methyl-2-pyrrolidone, γ-butyrolactone, diethylether, ethyleneglycoldimethylether, diglyme, tetrahydrofuran, acetylacetone, or acetonitrile.

The precursor solution including the tin oxide semiconductor may be prepared at a temperature in the range of about 60° C. to about 80° C. A semiconductor type of the tin oxide semiconductor may be controlled by selecting the valence number of the tin compound in the precursor solution of the tin compound. A divalent tin salt (having a +2 valence) may be used to form a p-type tin oxide semiconductor. A quadrivalent tin salt (having a +4 valence) may be used to form an n-type tin oxide semiconductor. The divalent tin salt and the quadrivalent tin salt for forming tin oxide semiconductors are the same as described above.

A tin oxide of a p-type semiconductor and a tin oxide of an n-type semiconductor may be prepared by, e.g., the reactions shown below.

2SnCl₂+O₂→2SnO+2Cl₂(⇑):p-type tin oxide semiconductor

SnCl₄+O₂→SnO₂+2Cl₂(⇑):n-type tin oxide semiconductor

The concentration of the tin compound in the precursor solution for the tin oxide semiconductor may be about 0.1 M to about 10 M. This concentration may help provide a semiconductor thin film having good electric properties.

Additionally, at least one additive selected from, for example, a dispersing agent, a binding agent, a compatibilizing agent, a stabilizing agent, a pH adjuster, a viscosity adjuster, an anti-foaming agent, a detergent, and a curing agent may be added to the precursor solution, which may help improve the characteristics or properties of the tin oxide semiconductor thin film.

The prepared precursor solution (S110) may be applied on the substrate (S120).

A suitable material may be used for the substrate according to the use of the tin oxide semiconductor thin film to be formed. If the tin oxide semiconductor thin film will constitute a semiconductor layer of a thin film transistor, the substrate may be, for example, glass or plastic. In addition, the substrate may further include other structural features of the thin film transistor such as a gate electrode, a gate insulating layer, a source/drain electrode, and/or the like.

The application method of the precursor solution may be, for example, spin coating, dip coating, inkjet printing, screen printing, a spray process, a roll-to-roll process, etc.

The substrate with the precursor solution applied thereon is subjected to heat treatment (S130). The solvent in the precursor solution may be evaporated during the heat treatment. A tin oxide semiconductor may be formed from the tin compound. The heat treatment may include a first heat treatment (e.g., a first bake) and a second heat treatment (e.g., a second bake). The first heat treatment may be performed at a temperature lower than that of the second heat treatment. The first heat treatment may be performed at a temperature of about 100° C. to about 300° C. for about 1 minute to about 10 minutes. The second heat treatment may be performed at a temperature of about 300° C. to about 500° C. for about 1 hour to about 2 hours. At least one of the first heat treatment and the second heat treatment may be performed in an oxygen atmosphere. For example, the heat treatment may be performed by using a hot-plate, a furnace, a laser, etc.

The formed tin oxide semiconductor thin film may include SnOₓ (1≦x≦2), for example, SnO, SnO₂, or a combination thereof. Additionally, the tin oxide semiconductor thin film may be amorphous. The concentration of holes or electrons of the tin oxide semiconductor thin film may vary depending on the concentration of the tin compound in the precursor solution.

Certain example methods of forming the tin oxide semiconductor thin film disclosed herein may enable the semiconductor thin film to be formed at a relatively low cost, e.g., by using a solution process. In certain example embodiments, the characteristics of the n-type semiconductor and the p-type semiconductor may be controlled by using only tin compounds without using any dopant.

In certain example embodiments, the valence of the tin compound used in the precursor solution may be selected based on the type of semiconductor thin film desired (e.g., n-type, p-type). For example, a tin compound having a first valence (e.g., II) may be selected to form a p-type tin oxide semiconductor. A tin compound having a second valence (e.g., IV) may be selected to form an n-type tin oxide semiconductor.

Certain methods for forming tin oxide semiconductors disclosed herein may be used to manufacture various devices according to intended uses, for example, one or more of a semiconductor layer, a gate electrode, a source/drain electrode in thin film transistor, an active layer, an interphase layer, and an electrode of a photovoltaic device. The electronic devices may include, for example, display devices, solar cells, etc. The tin oxide semiconductor thin film may exhibit substantially uniform characteristics when used to form a large area device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

A silicon oxide film (120 nm) as a gate insulator was formed by thermal oxidation on a gate electrode doped with a high concentration of a p-type semiconductor in a silicon substrate. A tin oxide semiconductor layer (channel length/width=150 μm/1000 μm) with a thickness of 30 nm was formed on top of the gate insulator according to the method described below (preparation of a tin oxide semiconductor precursor solution, and formation of a tin oxide semiconductor thin film), and a source electrode and a drain electrode with a thickness of 200 nm were formed on top of the tin oxide semiconductor layer via aluminum sputtering using a shadow mask.

Preparation of a Tin Oxide Semiconductor Precursor Solution

SnCl₂ (II) was mixed with anhydrous 2-methoxyethanol at 70° C. for about 20 minutes by using a stirring bar. The mixture was prepared by adding 0.5688 g of SnCl₂ (II) per 10 mL of 2-methoxyethanol, and the molarity of the mixture solution was 0.3 M. Impurities were removed from the prepared solution by filtration through a 0.2 μm filter and a tin oxide semiconductor precursor solution was obtained.

Formation of a Tin Oxide Semiconductor Thin Film

The tin oxide semiconductor precursor solution was spin-coated on a glass substrate. The spin coating was performed at 3,000 rpm for 30 seconds. The spin-coated thin film was subjected to a first heat treatment on a hot plate kept at 300° C. for 5 minutes and then to a second heat treatment at 300° C. for 2 hours to thereby form a tin oxide semiconductor thin film with a thickness of 30 nm on the glass substrate.

### Example 2

A tin oxide semiconductor thin film was prepared in the same manner as in Example 1 except that the second heat treatment was performed at 500° C. instead of 300° C.

### Example 3

A tin oxide semiconductor thin film was prepared in the same manner as in Example 1 except that SnCl₄ (IV) was used instead of SnCl₂ (II)

### Example 4

A tin oxide semiconductor thin film was prepared in the same manner as in Example 3 except that the second heat treatment was performed at 500° C. instead of 300° C.

Evaluation of Characteristics of Thin Film Transistors

FIG. 2 illustrates a graph showing a drain current (Id) vs. a gate voltage (Vg) of thin film transistors according to Examples 1 to 4.

Referring to the graph of FIG. 2, the thin film transistors of Examples 1 and 2 exhibited the characteristics of a p-type semiconductor and a flow of a drain current (Id) occurred when a negative (−) gate voltage (Vg) was applied to gate electrode. The thin film transistor of Example 3 exhibited off-current characteristics of an n-type semiconductor and no flow of a drain current (Id) occurred when a negative (−) gate voltage (Vg) was applied to gate electrode. The thin film transistor of Example 4 exhibited the characteristics of an n-type semiconductor and a flow of a drain current (Id) occurred when a positive (+) gate voltage (Vg) was applied to gate electrode.

In addition, referring to FIG. 2, the size of the threshold voltage and the drain current may vary according to the tin valence of tin chloride and the temperature of heat treatment in forming a tin oxide semiconductor thin film. For example, when SnCl₂ (II) was used, the size of the drain current (Id) in the thin film transistor of Example 2, in which the heat treatment was performed at 500° C., was greater than that of the thin film transistor of Example 1, in which heat treatment was performed at 300° C. Furthermore, the size of the drain current (Id) in the thin film transistors of Examples 1 and 2 (where SnCl₂ (II) was used) was greater than that of the drain current (Id) in the thin film transistors of Examples 3 and 4 (when SnCl₄ (IV) was used).

### Experimental Example 1

A tin oxide precursor solution and semiconductor thin film were prepared in the same manner as in Example 1, except that the second heat treatment was performed at 500° C. for 1 hour instead of 300° C. for 2 hours.

### Experimental Example 2

A tin oxide semiconductor thin film was prepared in the same manner as in Experimental Example 1 except that SnCl₄ (IV) was used instead of SnCl₂ (II).

### Measurement of Charge Carrier of a Tin Oxide Semiconductor Thin Film

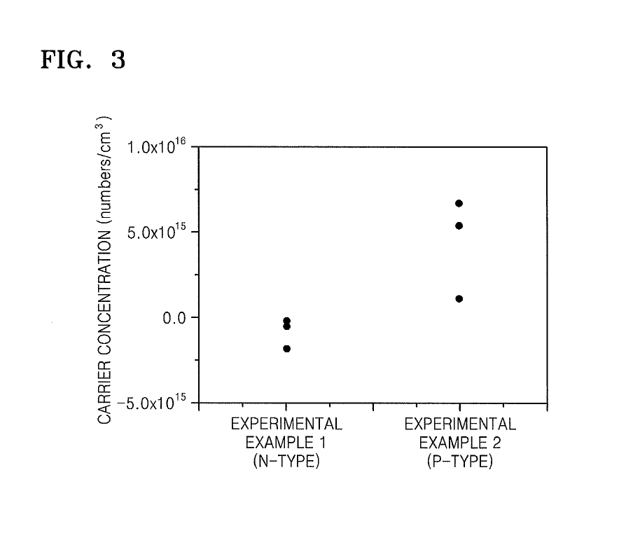

FIG. 3 illustrates a graph of a hole concentration according to Experimental Examples 1 and 2. The concentration of holes was measured via a “Hall effect measurement” by using HMS-3000 (Ecopia). Three tin oxide semiconductor thin films were prepared according to Experimental Examples 1 and 2, and hole concentrations were measured.

Referring to the graph of FIG. 3, the hole concentration in the tin oxide semiconductor thin film of the Experimental Example 1, where SnCl₂ (II) was used as a precursor, is very large. The tin oxide semiconductor thin film prepared according to Experimental Example 1 was a p-type semiconductor. In contrast, in the tin oxide semiconductor thin film of the Experimental Example 2, where SnCl₄ (IV) was used as a precursor, the concentration of holes in the tin oxide semiconductor thin film was close to 0. The tin oxide semiconductor thin film prepared according to Experimental Example 2 was an n-type semiconductor.

One or more embodiments may include a method of forming a tin oxide semiconductor thin film by using a solution process for controlling a semiconductor type. In certain example embodiments, the semiconductor type of a tin oxide semiconductor may be controlled, or chosen, by controlling, or selecting, the tin valence of the precursor tin compound of the tin oxide semiconductor.

By way of summation and review, an oxide semiconductor may have many advantages. For example, it may have higher electron mobility than non-crystalline silicon, superior low temperature process relative to polycrystalline silicon, and may be transparent to visible light. Thus, an oxide semiconductor may be used to manufacture a semiconductor layer of an electronic device such as a thin film transistor.

Various materials including base materials such as In, Zn, etc., to which various metals are added, have been used to form oxide semiconductors. Thin films made of oxide semiconductors may be manufactured by vacuum processes such as pulsed laser deposition (PLD), sputtering, atomic layer deposition (ALD), and the like. However, when indium (In) is used in such materials, the manufacturing cost of the oxide semiconductors increases, and in the case of using a vacuum process, further manufacturing costs may be incurred.

Tin oxide semiconductors have been considered as oxide semiconductors to replace In-containing oxide semiconductors. Oxide semiconductors may have n-type semiconductor characteristics, but it may be desirable to form an oxide semiconductor having p-type semiconductor characteristics. Furthermore, it may be desirable to form both n-type and p-type tin oxide semiconductors while reducing manufacturing costs, e.g., by using a solution process.

As described herein, in certain example embodiments, the conductivity type (p or n) of a tin oxide semiconductor may be controlled by selecting a precursor tin compound having a particular tin valence for the tin oxide semiconductor. Selecting a tin compound having a particular valence may enable the type of the semiconductor to be controlled and/or selected. A solution process may be used. In certain example instances, the manufacturing cost of the tin oxide semiconductor may be reduced. Furthermore, a tin oxide semiconductor thin film according to certain example embodiments may have good electrical properties and/or improved characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of forming a tin oxide semiconductor thin film, the method comprising:
preparing a precursor solution including a tin compound;
applying the precursor solution on a substrate; and
subjecting the substrate with the precursor solution applied thereon to a heat treatment to form the tin oxide semiconductor thin film,
wherein the tin compound used in the precursor solution has a different tin valence according to a semiconductor type of the tin oxide semiconductor thin film.

2. The method of forming a tin oxide semiconductor thin film as claimed in claim 1, wherein the preparing of the precursor solution includes dissolving the tin compound in a solvent.

3. The method of forming a tin oxide semiconductor thin film as claimed in claim 1, wherein the tin compound is selected from a divalent tin salt and a quadrivalent tin salt.

4. The method of forming a tin oxide semiconductor thin film as claimed in claim 3, wherein the tin compound is a divalent tin salt, and the divalent tin salt includes at least one of tin(II) chloride, tin(II) iodide, tin(II) chloride dihydrate, tin(II) bromide, tin(II) fluoride, tin(II) oxalate, tin(II) sulfide, or tin(II) acetate.

5. The method of forming a tin oxide semiconductor thin film as claimed in claim 3, wherein the tin compound is a quadrivalent tin salt, and the quadrivalent tin salt includes at least one of tin(IV) chloride, tin(IV) chloride pentahydrate, tin(IV) fluoride, tin(IV) iodide, tin(IV) sulfide or tin(IV) tert-butoxide.

6. The method of forming a tin oxide semiconductor thin film as claimed in claim 3, wherein the tin compound is a divalent tin salt, and the divalent tin salt is used to form a p-type tin oxide semiconductor.

7. The method of forming a tin oxide semiconductor thin film as claimed in claim 6, wherein the p-type tin oxide semiconductor includes SnO.

8. The method of forming a tin oxide semiconductor thin film as claimed in claim 3, wherein the tin compound is a quadrivalent tin salt, and the quadrivalent tin salt is used to form an n-type tin oxide semiconductor.

9. The method of forming a tin oxide semiconductor thin film as claimed in claim 8, wherein the n-type tin oxide semiconductor includes SnO₂.

10. The method of forming a tin oxide semiconductor thin film as claimed in claim 1, wherein a concentration of the tin compound relative to the total precursor solution is from about 0.1 M to about 10 M.

11. The method of forming a tin oxide semiconductor thin film as claimed in claim 1, wherein the preparing of the precursor solution of the tin oxide semiconductor is performed at a temperature of about 50° C. to about 80° C.

12. The method of forming a tin oxide semiconductor thin film as claimed in claim 1, wherein the heat treatment includes a first heat treatment performed at a temperature of about 100° C. to about 300° C.

13. The method of forming a tin oxide semiconductor thin film as claimed in claim 12, wherein the heat treatment further includes a second heat treatment performed at a temperature of about 300° C. to about 500° C.

14. The method of forming a tin oxide semiconductor thin film as claimed in claim 13, wherein the first heat treatment is performed for about 1 minute to about 10 minutes, and the second heat treatment is performed for about 1 hour to about 3 hours.

15. The method of forming a tin oxide semiconductor thin film as claimed in claim 14, wherein at least one of the first heat treatment and the second heat treatment is performed in an oxygen atmosphere.

16. The method of forming a tin oxide semiconductor thin film as claimed in claim 1, wherein the precursor solution is applied on the substrate by spin coating, dip coating, inkjet printing, screen printing, a spray process, or a roll-to-roll process.

17. The method of forming a tin oxide semiconductor thin film as claimed in claim 1, wherein the tin oxide semiconductor thin film is amorphous.

18. The method of forming a tin oxide semiconductor thin film as claimed in claim 1, wherein the heat treatment is performed by using a hot-plate, a furnace, or via rapid heat treatment.

19. The method of forming a tin oxide semiconductor thin film as claimed in claim 1, wherein the heat treatment is performed in an oxygen atmosphere.

20. A method of forming a tin oxide semiconductor thin film, the method comprising:
preparing a precursor solution including a tin compound, the tin compound having a first valence or a second valence, wherein the first valence is different from the second valence;
applying the precursor solution on a substrate; and
subjecting the substrate and precursor solution applied thereon to a heat treatment to form the tin oxide semiconductor thin film,
wherein a semiconductor type of the tin oxide semiconductor thin film is controlled by selecting the tin compound having the first valence or the tin compound having the second valence.
